(19) United States
(12) Patent Application Publication
(10) Pub. No.: US 2001/0025361 A1
(43) Pub. Date: Sep. 27, 2001

(54) XOR code and serially concatenated encoder/decoder using the same

(76) Inventor: Sae-joon Kim, Seoul (KR)

Correspondence Address: SUGHRUE, MION, ZINN, MACPEAK & SEAS, PLLC, 2100 PENNSYLVANIA AVENUE, N.W., WASHINGTON, DC, 20037-3202, US

(21) Appl. No.: 09/737,823

(22) Filed: Dec. 18, 2000

(30) Foreign Application Priority Data
Dec. 18, 1999 (KR) 99-58925

(51) Int. Cl. H03M 13/03; H03M 13/00

(52) U.S. Cl. 714/786; 714/777

(57) ABSTRACT

An XOR code, and serially concatenated encoder/decoder are provided. The XOR code, in which input information bits are combined according to a combination order determined by a user and encoded at a code rate r by a modulo-2 operation, where 0<r≦1 The XOR code is linear-time encodable and decodable. Furthermore, since the serially concatenated encoder does not require an interleaver, input information bits can be encoded and then transmitted without a delay corresponding to the processing time of an interleaver.

### BACKGROUND OF THE INVENTION

1. Field of the Invention

The present invention relates to an encoder/decoder, and more particularly, to an XOR code and serially concatenated encoder/decoder using the same.

This application is based on Korean Application No. KPA 1999-58925, which is incorporated herein by reference for all purposes.

2. Description of the Related Art

In a digital mobile communication system, bit errors are likely to occur in data transmission due to characteristics of a radio channel. Thus, channel coding used for correcting bit errors produced in a transmission channel is one of most important technologies in a mobile communication system. A conventional channel code used in the mobile communication systems includes a convolutional code which is decoded by a Viterbi decoder, but most recently, a turbo code is becoming of great importance due to its excellent performance. A turbo code refers to an error-correcting code made from the parallel concatenation of convolutional codes, and its corrective capacity is known to be closer to the Shannon limit as the size of an interleaver becomes larger.

Besides the above-mentioned turbo code, there is a serially concatenated code consisting of a repetition code and a convolutional code. One example of a serially concatenated code is a repetition-accumulation code introduced by H. Tin and R. J. McEliece (Repeat-Accumulate Codes, AAECC-13, November 1999).

FIG. 1 is a block diagram showing a repetition-accumulation encoder and a repetition-accumulation decoder. Referring to FIG. 1, the repetition-accumulation encoder includes a repetition encoder 100, an interleaver 102, and an accumulation encoder 104, while the repetition-accumulation decoder includes an accumulation decoder 110, a deinterleaver 112, a repetition decoder 114, and an interleaver 116. The repetition encoder 100 copies each bit of input information according to a code rate r and then outputs the copied results. For example, assuming that the input information bits are ‘10’ and a code rate is ⅓, the repetition encoder 100 outputs ‘111000’. The interleaver 102 interleaves repetitively encoded data according to a predetermined rule. The accumulation encoder 104 encodes by accumulating the interleaved data according to a predetermined rule. Data encoded in the accumulation encoder 104 becomes a codeword of the overall code to be transmitted via a channel. In this case, since the code rate of the repetition encoder 100 is r and the code rate of the accumulation encoder 104 is 1, the overall code rate is r.

The accumulation decoder 110, the deinterleaver 112, and the repetition decoder 114 decode received data and feedback data using a conventional belief propagation algorithm (BPA). The interleaver 116 interleaves the decoded data again in accordance with the same rule as the interleaver 102 on the transmission side, and feeds back the interleaved data to the accumulation decoder 110.

However, while the repetition encoder 100 is relatively simple in operation, Hamming distances between the output data are small so that error correction is made difficult. Thus, the interleaver 102 needs to be used. The accumulation encoder 104 cannot transform input data since the input data is sequentially accumulated and encoded. Furthermore, if the code rate is low, the repetition-accumulation encoder and decoder reaches a theoretical limit in terms of error correction capacity.

### SUMMARY OF THE INVENTION

To solve the above problems, it is an objective of the present invention to provide an XOR code, which is modulo-2 operated and encoded according to a combination order determined by a user, and a serially concatenated encoder and serially concatenated decoder using the XOR code.

Accordingly, to achieve the above objective, the present invention provides an XOR code, wherein input information bits are combined according to a combination order determined by a user and encoded at a code rate r by a modulo-2 operation, where 0<r≦1.

The present invention also provides a serially concatenated encoder using the XOR code, that includes an XOR encoder which combines input information bits according to a combination order determined by a user and performs a modulo-2 operation to encode the input information bits at a code rate r, where 0<r≦1, and a convolutional code encoder which encodes the output data of the XOR encoder according to a predetermined convolution formula.

The present invention also provides a serially concatenated decoder using an XOR code that includes a convolutional decoder which decodes a data sequence corresponding to input information bits on a transmission side among received data, and compares the encoded data with the received data to obtain a value which best matches the received data, and an XOR decoder which corrects errors in the output data of the convolutional decoder using a parity-check matrix determined by an encoding matrix on a transmission side.

### BRIEF DESCRIPTION OF THE DRAWINGS

The above objectives and advantages of the present invention will become more apparent by describing in detail a preferred embodiment thereof with reference to the attached drawings in which:

FIG. 1 is a block diagram showing a repetition-accumulation encoder and a repetition-accumulation decoder;

FIG. 2 is a block diagram showing a serially concatenated encoder and a serially concatenated decoder using an XOR code according to the present invention; and

FIG. 3 illustrates an example of the operation of the XOR encoder of FIG. 2.

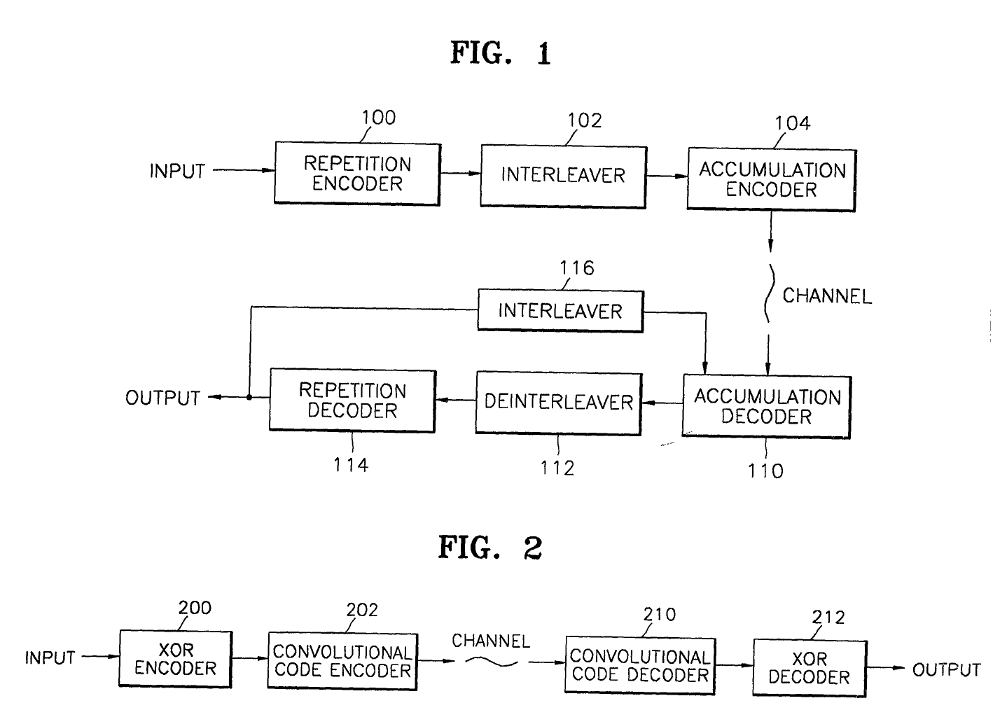

### DETAILED DESCRIPTION OF THE INVENTION

Referring to FIG. 2, a serially concatenated encoder according to the present invention includes an XOR encoder 200 and a convolutional code encoder 202. A serially concatenated decoder according to the invention includes a convolutional code decoder 210 and an XOR decoder 212.

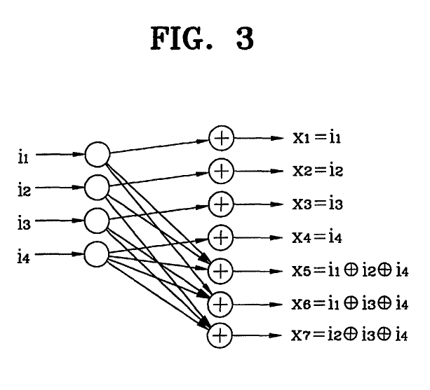

The XOR encoder 200 combines n bits of input data according to a predetermined rule to modulo-2 operate the combined result and then output k bits of data. Referring to FIG. 3, the input information bits i₁, i₂, i₃, and i₄ are combined according to a predetermined rule and modulo-2 operated to output an encoded codeword xᵢ (where i equals 1, 2, . . . , 7). An example of a combination rule is as follows:

x₁=i₁ x₂=i₂ x₃=i₃ x₄=i₄ x₅=i₁⊕i₂⊕i₄ x₆=i₁⊕i₃⊕i₄ x₇=i₂⊕i₃⊕i₄ (1)

where ⊕ denotes a modulo-2 operation. If Equation (1) is rearranged, Equation (2) is formed as follows:

\vec{x}=(i₁,i₂,i₃,i₄,i₁⊕i₂⊕i₄,i₁⊕i₃⊕i₄,i₂⊕i₃⊕i₄) (2)

If it is further generalized, Equation (3) is formed as follows:

$${X}^{->} = {\sum }_{{j}^{′} ε {I}_{J}} {i}_{j′} mod2$$

where Iⱼ={k′|k′ε{1, 2, . . . , k}}, and k is a natural number.

The XOR code can be a systematic Hamming code defined by a generator matrix G. An output vector \vec{x} equals G\vec{i}. In this case, the generator matrix G is a systematic matrix that makes the first k bits of each codeword copy input information bits without any transformation. The generator matrix G corresponding to Equation (2) is expressed by the following matrix:

$$G = ( \begin{matrix}1000110 \\ 0100101 \\ 0010011 \\ 0001111\end{matrix} ) \qquad ( 4 )$$

The convolutional code encoder 202 encodes the output of the XOR encoder 200 in accordance with a convolution formula appropriately selected by the user. The output of the convolutional code encoder 202 is a codeword of the overall code. If r1 and r2 denote the code rates of the XOR encoder 200 and the convolutional code encoder 202, respectively, where if 0<r1≦1 and 0<r2≦1, the overall code rate is r1×r2. Thus encoded data is transmitted via a channel.

The convolutional code decoder 210 and the XOR decoder 212 decode the received data using BPA which is well known in the art. According to a conventional maximum a posteriori decoding algorithm, the convolutional code decoder 210 decodes the data sequence corresponding to the input information bits on the transmission side among the received data, and compares the decoded data with the received data to obtain a value which best matches the received data. The XOR decoder 212 applies BPA to a parity-check matrix determined as the systematic matrix G to correct errors in the output data of the convolutional code decoder 210.

An XOR code according to the present invention is linear-time encodable and decodable. Furthermore, since a serially concatenated encoder using the XOR code according to the invention does not need an interleaver, input information bits can be encoded and then transmitted without a delay in the processing time due to an interleaver.

Although the preferred embodiment of the present invention has been described, it will be understood by those skilled in the art that the present invention should not be limited to the described preferred embodiment, but that various changes to the scope of the present invention as defined by the appended claims are possible.

What is claimed is:

1. An XOR code having input information bits, which are combined according to a combination order determined by a user and are encoded at a code rate r by a modulo-2 operation, wherein 0<r≦1.

2. A serially concatenated encoder using an XOR code, the serially concatenated encoder comprising:
an XOR encoder which combines input information bits according to a combination order determined by a user and performs a modulo-2 operation on the combined result to encode it at a code rate r, wherein 0<r≦1; and
a convolutional code encoder which encodes the output data of the XOR encoder according to a predetermined convolution formula.

3. The serially concatenated encoder of claim 2, wherein the XOR encoder is a means for generating a systematic Hamming code.

4. A serially concatenated decoder using an XOR code, the serially concatenated decoder comprising:
a convolutional decoder which decodes a data sequence corresponding to input information bits on a transmission side among received data, and compares encoded data with the received data to obtain a value which best matches the received data; and
an XOR decoder which corrects errors in output data of the convolutional decoder using a parity-check matrix determined by an encoding matrix on the transmission side.

5. An encoder/decoder structure for a digital mobile communication system, comprising:
a serially concatenated encoder using an XOR code, the serially concatenated decoder comprising:
an XOR encoder operable to combine n bits of input data according to a predetermined combination rule and modulo-2 operate the combined result to encode the combined result at a code rate r1; and
a convolutional code encoder operable to encode an output of the XOR encoder according to a predetermined convolution formula at a code rate r2; and
a serially concatenated decoder using the XOR code, the serially concatenated decoder comprising:
a convolutional decoder which decodes a data sequence corresponding to the input data on a transmission side from among received data, and compares encoded data with the received data to obtain a value which best matches the received data; and
an XOR decoder which corrects errors in output data of the convolutional decoder using a parity-check matrix determined by an encoding matrix on the transmission side,
wherein an output of the convolutional code encoder is a codeword of the XOR code that is transmitted via a channel to the serially concatenated decoder, and wherein an overall code rate of the serially concatenated encoder is r1×r2.
